(19) United States
(12) Patent Application Publication
(10) Pub. No.: US 2007/0262334 A1
(43) Pub. Date: Nov. 15, 2007

(54) FULL COLOR LED DISPLAY

(76) Inventors: Wei-Pang Chiang, Chung Ho City (TW); Zeng-Qin Jiang, Chung Ho City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/423,929

(22) Filed: Jun. 13, 2006

(30) Foreign Application Priority Data
May 10, 2006 (TW) 095208030

(51) Int. Cl. H01L 33/00

(52) U.S. Cl. 257/89

(57) ABSTRACT

A full color LED display, comprised a plurality of full color luminant units, is characteristic of: each of the full color luminant units comprises four LEDs distributed in a cross type; each of the LEDs has a polygon top; each space between any two adjacent LEDs of the LEDs is smaller than or equal to 1.2 millimeters; and each space between any two adjacent full color luminant units of the full color luminant units is smaller than or equal to 8 millimeters. The full color luminant unit comprises two red LED, one green LED and one blue LED while the LEDs are full-length LEDs. Moreover, a LED panel's virtual pixel technology is applied for the full color LED display so that the full color LED display has higher image density, better signal mixing, and higher resolution thereof.

### 1. FIELD OF THE INVENTION

The present invention relates to a full color luminant unit and an application for a full color LED display with the full color luminant unit, and more particularly to a trichromatic LED assembly that has higher image density, better signal mixing, and higher resolution thereof.

### 2. DESCRIPTION OF RELATED ART

The LED (Light Emitting Diode) is an important product of the recently advance of science and technology. Forty years ago, the red LED born so that the research of the III-V family had made a great improvement. Moreover, the discoveries of the green LED and the yellow LED thrown the industrial circles into the research and the manufacture of the LED applications. The discovery of AlGaN made brightness of the blue LED and the green LED higher, and the trichromatic LEDs, the red LED, blue LED and green LED, are completed to reach the full color of display. Recently, the full color LED display even substitutes the conventional display while the LED has small package size and flattening view with some features, low power, longer life, higher patience, directly lightening and correct color. Besides, the full color LED display is popularized because of that the higher LED brightness, the better LED success rate, and the lower LED cost.

At present, the full color LED displays in the market are distinguished into a LED bulb type and SMD-LED (Surface Mounting Device LED) type while the two types make a great difference among that the full color luminant unit of the full color LED display is the trichromatic LED bulb type or the trichromatic SMD-LED type. Refer to the FIG. 1, the FIG. 1 is a partial exploded view of a conventional full color LED bulb. The structure of a conventional full color LED bulb unit has trichromatic full-length LED bulbs (10 [symbol] 10′ [symbol] 11 [symbol] 12) electrically connected with the electric board (13). However, the trichromatic full-length LED bulbs (10 [symbol] 10′ [symbol] 11 [symbol] 12) are spread on a plane, and each bulb has big package size. The distance Between centers of each two adjacent full-length LEDs bulbs is long so that the trichromatic LED bulbs (10 [symbol] 1 [symbol] ′ [symbol] 11 [symbol] 12) have low image density, bad signal mixing, and low resolution.

Refer to the FIG. 2, the FIG. 2 is a top view of a conventional trichromatic SMD-LED. One of the prior arts discloses a trichromatic SMD-LED (Surface Mounted Devices LED), a trichromatic overlaid full color LED, comprises: a base which has a red LED grain (20); a blue LED grain (21) and a green LED grain (22) are independent light components. The blue LED grain (21) and the green LED grain (22) cover a part of the top of the red LED (20) while another part of the top of the red LED grain (20) can emit light still. However, the red LED, the blue LED and the green LED are SMD-LED so that the cooling efficiency is worse than the full-length LED. In other words, the SMD-LED produce more heat during the operation thereof. When the trichromatic SMD-LED brightens, the red LED of the full color luminant unit is too close the blue and green LED to make the cooling efficiency worse. The higher temperature not only reduces the SMD-LED life but also damages the SMD-LED. On the other hand, it is not the original intention, increasing the distance between the adjacent SMD-LEDs, which makes the trichromatic full-length LED bulb lower density, worse signal mixing, and lower resolution thereof.

In the prior arts, the full color LED display adopts a trichromatic LED bulb or a trichromatic SMD-LED to be a full color luminant unit. There is no solution for improving full color performance and cooling efficiency so that there is a great demand for a full color LED display with full color luminant units.

### SUMMARY OF THE INVENTION

The primary objective of the present invention is to provide a full color luminant unit that has high image density and good signal mixing by different LEDs with different color.

Another objective of the present invention is to provide a full color luminant LED display that has high image density, good signal mixing, and high resolution by application of the full color luminant unit.

A full color luminant unit, applied for a full color LED display comprised four LEDs distributed in a cross type, is characteristic of: each of the LEDs has a polygon top, and each space between any two adjacent LEDs of the LEDs is smaller than or equal to 1.2 millimeters.

Moreover, the polygon top each of the LEDs has includes a square top, a trapezoid top, a triangular top and a hexagonal top.

Besides, there is another embodiment. A full color LED display, comprised a plurality of full color luminant units, is characteristic of: each of the full color luminant units comprises four LEDs distributed in a cross type; each of the LEDs has a polygon top; each space between any two adjacent LEDs of the LEDs is smaller than or equal to 1.2 millimeters; and each space between any two adjacent full color luminant units of the full color luminant units is smaller than or equal to 8 millimeters. The full color luminant unit comprises two red LED, one green LED and one blue LED while the LEDs are full-length LEDs. Moreover, a LED panel's virtual pixel technology is applied for the full color LED display so that the full color LED display has higher image density, better signal mixing, and higher resolution thereof.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

These and other modifications and advantages will become even more apparent from the following detained description of a preferred embodiment of the invention and from the drawings in which:

FIG. 1 is a partial exploded view of a conventional full color LED bulb;

FIG. 2 is a top view of a conventional trichromatic SMD-LED;

FIG. 3 is a perspective view of a first embodiment of the full color LED display the invention.

FIG. 4 is a top view of the first embodiment of the full color LED display the invention.

FIG. 5 is a top view of a second embodiment of the full color LED display the invention.

FIG. 6 is a top view of a third embodiment of the full color LED display the invention.

FIG. 7 is a top view of a fourth embodiment of the full color LED display the invention.

FIG. 8 is a top view of a fifth embodiment of the full color LED display the invention.

FIG. 9 is a top view of a sixth embodiment of the full color LED display the invention.

FIG. 10 is a top view of a seventh embodiment of the full color LED display the invention.

FIG. 11 is a top view of a eighth embodiment of the full color LED display the invention.

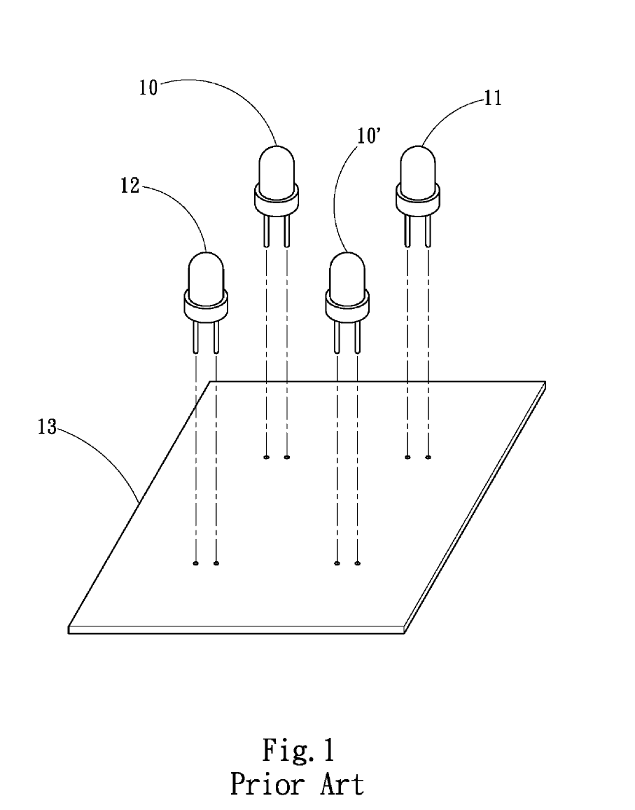

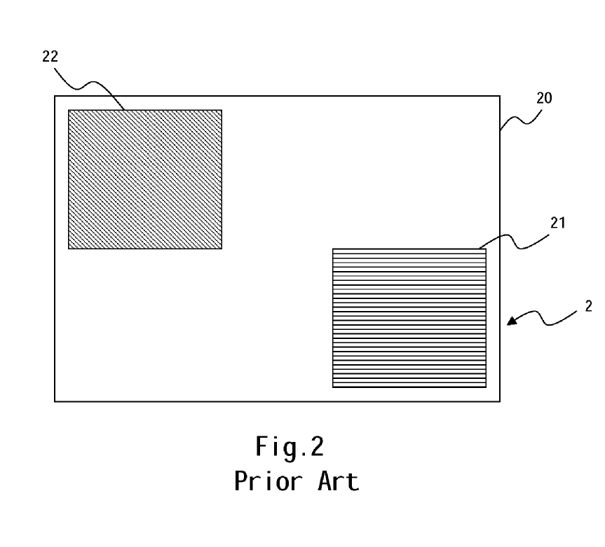

### DESCRIPTION OF THE PREFERRED EMBODIMENTS

Hereinafter, the present invention will be described by way of illustrative examples with reference to the accompanying drawings.

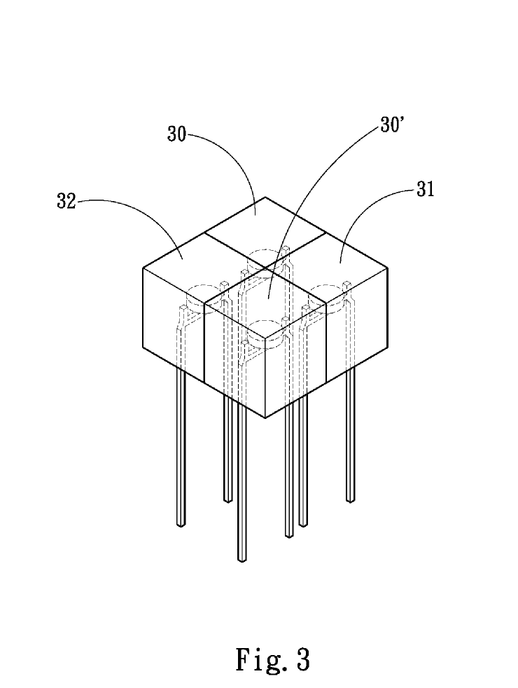

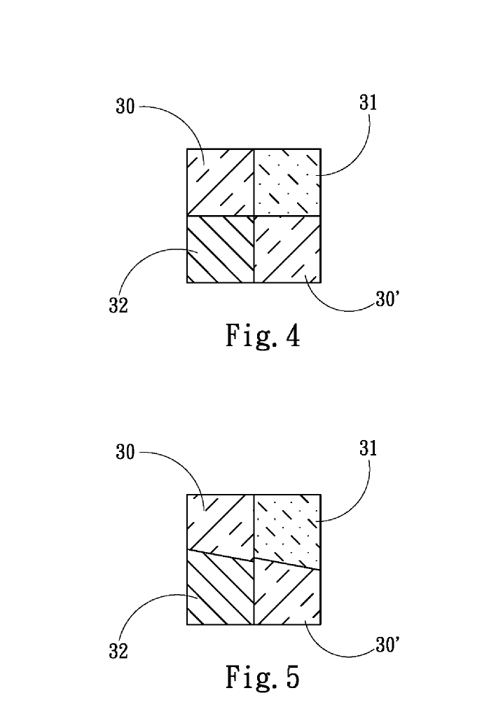

Refer to FIG. 3 and FIG. 4 for a first embodiment of the present invention. The FIG. 3 is a perspective view of the first embodiment of the invention, and FIG. 4 is a top view of the first embodiment of the invention. The present invention provides a full color luminant unit, which is suitable for a full color LED display (no showed in the figures). The full color luminant unit includes four LEDs, and the FIG. 4 shows exemplary arrangements of the LEDs. The LEDs, which distribute in a cross type, include two red LED (30 [symbol] 30′), a green LED (31) and a blue LED (32) while the LEDs (30, 30′, 31 and 32) form a full-length LED. One particular of the LEDs (30, 30′, 31 and 32) is that each of the LEDs (30, 30′, 31 and 32) has a square top to form a square top of the full color luminant unit while another particular of the LEDs (30, 30′, 31 and 32) is that each space between any two adjacent LEDs of the LEDs (30, 30′, 31 and 32) is smaller than or equal to 1.2 millimeters. A LED panel's virtual pixel technology can be applied for the LEDs (30, 30′, 31 and 32) distributed in the cross type to improve the resolution thereof. The LED panel's virtual pixel technology is a controlling method for multiple operation of each pixel to increase the resolution and reach the better display effect so that an image has higher resolution under the same LED number. In more detail, the LED panel's virtual pixel technology makes the same resolution as the quarter pixel area of the general display technology.

Refer to FIG. 5 for a second embodiment of the present invention. In the second embodiment of the present invention, each of the LEDs (30, 30′, 31 and 32) having a trapezoid top is different from the first embodiment.

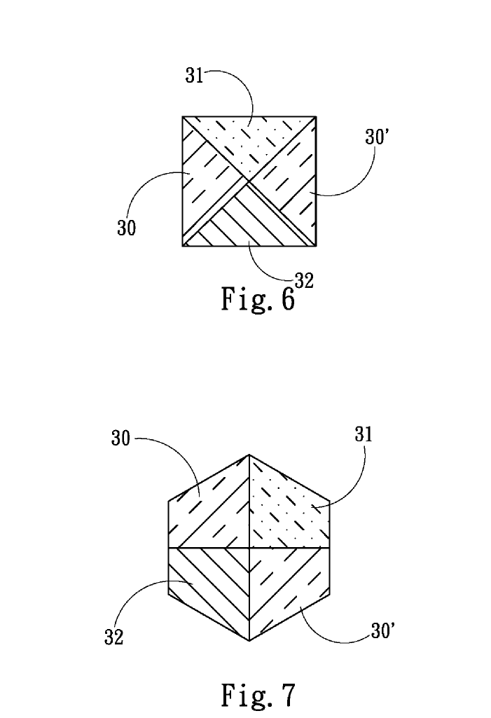

Refer to FIG. 6 for a third embodiment of the present invention. In the third embodiment of the present invention, each of the LEDs (30, 30′, 31 and 32) having a triangular top is different from the first embodiment.

Refer to FIG. 7 for a fourth embodiment of the present invention. In the fourth embodiment of the present invention, each of the LEDs (30, 30′, 31 and 32) having a trapezoid top to form a hexagonal top of the full color luminant unit is different from the first embodiment.

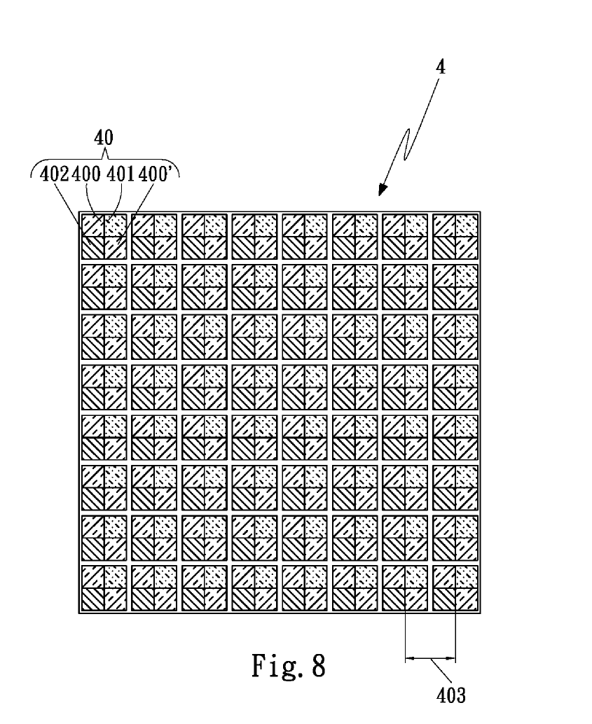

Refer to FIG. 8 for a fifth embodiment of the present invention. The present invention also provide a full color LED display (4) including a plurality of full color luminant units (40) and an electrical assembly (no showed in the figures), wherein the electrical assembly has a plurality of jacks and LED controllers. Each of the jacks can engage some pin of the full-length LED for electrically connecting, and each of the LED controllers can control the full-length LED engaged with the jack for making the full-length LED be glittering. One characteristic of the full color LED display (4) is that the full color luminant unit (40) has a red LED (400), a red LED (400′), a green LED (401) and a blue LED (402). All of the LEDs (400 [symbol] 400′ [symbol] 401 [symbol] 402) are full-length LEDs engaged with the according jacks. Each of the LEDs (400, 400′, 401 and 402), which distribute in a cross type, has a square top to form a square top of the full color luminant unit while each space between any two adjacent LEDs of the LEDs (400, 400′, 401 and 402) is smaller than or equal to 1.2 millimeters and each space between any two adjacent full color luminant unit between centers (403) is smaller than or equal to 8 millimeters. The LED panel's virtual pixel technology also can be applied for the LEDs (400, 400′, 401 and 402) distributed in the cross type to improve the resolution thereof. The LED panel's virtual pixel technology is a controlling method for multiple operation of each pixel to increase the resolution of the full color LED display and reach the better display effect so that an image has higher resolution under the same LED number. In more detail, the LED panel's virtual pixel technology makes the full color LED display have the same resolution with the quarter pixel area of the general display technology. In other words, the LED panel's virtual pixel technology makes the full color LED display have the fourfold resolution with the same pixel area of the general display technology.

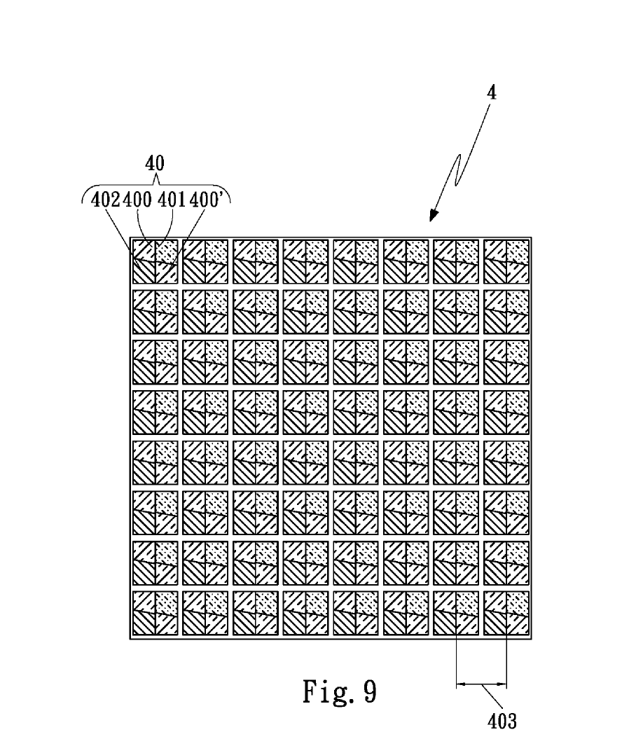

Refer to FIG. 9 for a sixth embodiment of the present invention. In the sixth embodiment of the present invention, each of the LEDs (400, 400′, 401 and 402) having a trapezoid top is different from the fifth embodiment.

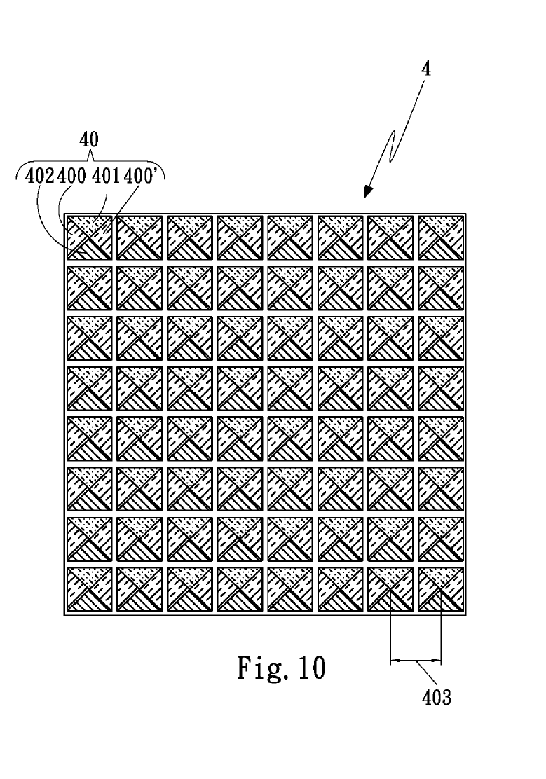

Refer to FIG. 10 for a seventh embodiment of the present invention. In the seventh embodiment of the present invention, each of the LEDs (400, 400′, 401 and 402) having a triangular top is different from the fifth embodiment.

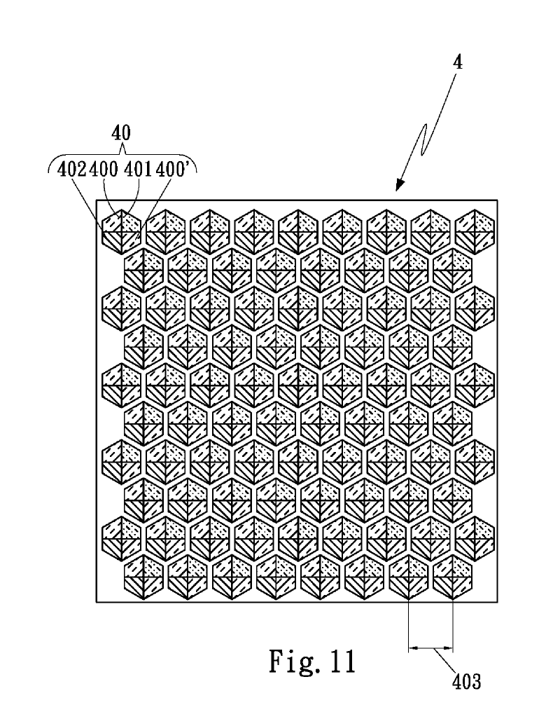

Refer to FIG. 11 for an eighth embodiment of the present invention. In the eighth embodiment of the present invention, each of the LEDs (400, 400′, 401 and 402) having a trapezoid top to form a hexagonal top of the full color ruminant unit is different from the fifth embodiment.

In conclusion, because of that the present invention, the full color ruminant unit and the full color LED display, has trichromatic LEDs forming as polygon and having a determinate interval and a cross distributing type, the problems, too larger volume and too longer between center, of the conventional trichromatic LED bulb are prevent. Moreover, the present invention can be applied with the LED panel's virtual pixel technology to make the higher image density, the better signal mixing, and the higher resolution thereof. At last, the present invention, the full color ruminant unit and the full color LED display, is constituted of the full-length LED so that the thermal power is smaller enough for preventing the damage and for ensuring life thereof.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments that do not depart from the spirit and scope of the invention.

What is claimed is:

1. A full color luminant unit, applied for a full color LED display comprised four LEDs distributed in a cross type, is characteristic of:
each of the LEDs has a polygon top, and each space between any two adjacent LEDs of the LEDs is smaller than or equal to 1.2 millimeters.

2. The full color luminant unit of claim 1, wherein each of the LEDs are selected from a full-length LED.

3. The full color luminant unit of claim 1, wherein each of the LEDs has a square top.

4. The full color luminant unit of claim 1, wherein each of the LEDs has a trapezoid top.

5. The full color luminant unit of claim 1, wherein each of the LEDs has a triangular top.

6. The full color luminant unit of claim 1, wherein the full color luminant unit has a polygon top.

7. The full color luminant unit of claim 1, wherein the LEDs comprise at least a red LED, a green LED and a blue LED.

8. The full color luminant unit of claim 7, wherein the LEDs comprise two red LEDs, one green LED and one blue LED.

9. The full color luminant unit of claim 8, wherein the LEDs comprise the red LEDs are not adjacent.

10. The full color luminant unit of claim 9, wherein the full color luminant unit is applied with a LED panel's virtual pixel technology.

11. A full color LED display, comprised a plurality of full color luminant units, is characteristic of:
each of the full color luminant units comprises four LEDs distributed in a cross type;
each of the LEDs has a polygon top;
each space between any two adjacent LEDs of the LEDs is smaller than or equal to 1.2 millimeters; and
each space between any two adjacent full color ruminant units of the full color ruminant units is smaller than or equal to 8 millimeters.

12. The full color LED display of claim 11, wherein each of the LEDs are selected from a full-length LED.

13. The full color LED display of claim 11, wherein each of the LEDs has a square top.

14. The full color LED display of claim 11, wherein each of the LEDs has a trapezoid top.

15. The full color LED display of claim 11, wherein each of the LEDs has a triangular top.

16. The full color LED display of claim 11, wherein wherein the full color ruminant unit has a polygon top.

17. The full color LED display of claim 11, wherein the LEDs comprise at least a red LED, a green LED and a blue LED.

18. The full color LED display of claim 17, wherein the LEDs comprise two red LEDs, one green LED and one blue LED.

19. The full color LED display of claim 18, wherein the LEDs comprise the red LEDs are not adjacent.

20. The full color LED display of claim 19, wherein the full color ruminant unit is applied with a LED panel's virtual pixel technology.
